(19) United States
(12) Patent Application Publication
(10) Pub. No.: US 2013/0120327 A1
(43) Pub. Date: May 16, 2013

(54) STORAGE CAPACITOR FOR ELECTROMECHANICAL SYSTEMS AND METHODS OF FORMING THE SAME

(71) Applicants: Jae Hyeong Seo, Pleasanton, CA (US); Ming-Hau Tung, San Francisco, CA (US); Marc M. Mignard, San Jose, CA (US); Rihui He, San Jose, CA (US)

(72) Inventors: Jae Hyeong Seo, Pleasanton, CA (US); Ming-Hau Tung, San Francisco, CA (US); Marc M. Mignard, San Jose, CA (US); Rihui He, San Jose, CA (US)

(73) Assignee: Qualcomm Mems Technologies, Inc., San Diego, CA (US)

(21) Appl. No.: 13/533,778

(22) Filed: Jun. 26, 2012

Related U.S. Application Data
(60) Provisional application No. 61/558,657, filed on Nov. 11, 2011.

(51) Int. Cl. G06F 3/038; G02B 26/00; G06T 1/00; H01L 21/98

(52) U.S. Cl. 345/204; 438/23; 359/291; 345/418; 257/E21.705

(57) ABSTRACT

This disclosure provides systems, methods and apparatus for storage capacitors. In one aspect, a device includes an array having at least a first display element and a second display element, at least one switch configured to control a flow of charge between a source and the first display element, and at least one interferometric optical mask structure disposed in a non-active area of the array between the first display element and the second display element. The optical mask structure includes a storage capacitor formed by a first conductive layer and a second conductive layer. The storage capacitor is electrically coupled to the at least one switch and the first display element.

### CROSS-REFERENCE TO RELATED APPLICATIONS

The disclosure claims priority to U.S. Provisional Patent Application No. 61/558,657 filed Nov. 11, 2011 entitled “STORAGE CAPACITOR FOR ELECTROMECHANICAL SYSTEMS AND METHODS OF FORMING THE SAME,” which is assigned to the assignee hereof. The disclosure of the prior application is considered part of, and is incorporated by reference in, this disclosure.

### TECHNICAL FIELD

This disclosure relates to electromechanical systems.

### DESCRIPTION OF THE RELATED TECHNOLOGY

Electromechanical systems (EMS) include devices having electrical and mechanical elements, actuators, transducers, sensors, optical components (e.g., minors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

In an EMS device, the reflective membrane can be moved between an actuated position and a relaxed position by application of a voltage between an electrode coupled to the reflective membrane and a stationary electrode. However, charge leakage from the movable reflective membrane can impact the performance of the EMS device. For example, the refresh rate of the device can be affected by charge leakage. Accordingly, there is a need for reducing the impact of charge leakage and for improving the operational performance of EMS devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in a device including an array, at least one switch, a storage capacitor, and at least one interferometric optical mask structure. The array includes at least a first display element and a second display element with each display element including a first electrode and a second electrode. The at least one switch is configured to control a flow of charge between a source and the first display element. The storage capacitor has a first capacitor electrode and a second capacitor electrode. The first capacitor electrode is electrically connected to the first electrode of the first display element. The at least one interferometric optical mask structure is disposed in a non-active area of the array between the first display element and the second display element. The optical mask structure includes a partially reflective and partially transmissive and partially absorptive first conductive layer, a reflective second conductive layer, and a spacer layer disposed between the first conductive layer and the second conductive layer. One of the first capacitor electrode and the second capacitor electrode includes one of the first conductive layer and the second conductive layer

In some aspects, one of the first capacitor electrode and the second capacitor electrode can include the first conductive layer and the other of the first capacitor electrode and the second capacitor electrode can include the second conductive layer. In some aspects, the device can also include a third conductive layer formed over the second conductive layer and a second spacer layer disposed between the third conductive layer and the second conductive layer with the third conductive layer and the second conductive layer forming the storage capacitor. In some aspects, the at least one switch can include a thin-film transistor. In some aspects, the thin-film transistor can include a drain that can be electrically coupled to the second conductive layer and to the first electrode, or the drain can be electrically coupled to the second conductive layer and the first electrode. In some aspects, a passivation layer can be disposed between at least a portion of the optical mask structure and the first display element. In some aspects, the device can also include a transistor contact layer electrically coupled to the drain of thin-film transistor and to the first electrode of the first display element. In some aspects, the second conductive layer of the optical mask can be disposed over the first conductive layer of the optical mask, at least a portion of the second conductive layer and the spacer layer can be patterned to form an opening, and a portion of the transistor contact layer can contact the first conductive layer in the opening. In some aspects, the first display element can be an interferometric modulator (IMOD) display element. In some aspects, the first electrode can be a stationary electrode and the second electrode can be a movable electrode.

Another innovative aspect of the subject matter described in this disclosure can be implemented in a method of forming a device. The method includes forming an optical mask structure for masking an optically non-active portion of the device. The optical mask structure includes a partially reflective and partially transmissive and partially absorptive first conductive layer, a reflective second conductive layer, and a spacer disposed between the first and second conductive layers. The first and second conductive layers form a storage capacitor. The method includes forming a storage capacitor having a first capacitor electrode and a second capacitor electrode. One of the first capacitor electrode and the second capacitor electrode includes one of the first conductive layer and the second conductive layer. The method also includes forming at least one switch configured to control a flow of charge between a source and a drain, forming a display element over the optical mask structure, the display element including a first electrode and a second electrode, and electrically coupling the drain of the at least one switch to the display element and at least one layer of the optical mask structure.

In some aspects, forming the at least one switch can include forming a thin-film transistor. Electrically coupling the at least one switch to the display element and the storage capacitor can include, for example, electrically coupling the drain to the second conductive layer and the first electrode, or electrically coupling the drain to the first conductive layer and the first electrode. In some aspects, forming the display element includes forming an interferometric modulator (IMOD).

Another innovative aspect of the subject matter described in this disclosure can be implemented in a device including means for controlling a flow of charge between a source and a drain, means for displaying information, and means for interferometrically masking light in a non-active area of the displaying means. The displaying means is electrically coupled to the drain of the charge controlling means and the masking means forms at least part of a storage capacitor that is electrically coupled to the drain of the charge controlling means. In some aspects, the displaying means can include an interferometric modulator (IMOD). In some aspects, the charge controlling means can include at least one switch. In some aspects, the masking means can include a partially reflective and partially transmissive and partially absorptive first conductive layer, a reflective second conductive layer, and a spacer layer disposed between the first conductive layer and the second conductive layer with one of the first conductive layer and the second conductive layer including a capacitor electrode of the storage capacitor. The first and second conductive layers can form the storage capacitor.

Another innovative aspect of the subject matter described in this disclosure can be implemented in a device including a first display element having a first electrode and a second electrode, at least one switch configured to control a flow of charge between a source and the first display element, and a storage capacitor having a a first capacitor electrode and a second capacitor electrode. The second electrode is movable relative to the first electrode. The at least one switch includes a first conductive layer, a second conductive layer, and a source/drain layer electrically connected to the first electrode of the display element. The first capacitor electrode is electrically connected to the first electrode of the display element. One of the first capacitor electrode and the second capacitor electrode includes one of the first conductive layer, the second conductive layer, and the source/drain of the at least one switch. In some aspects, the at least one switch can include a thin-film transistor having an active layer and a gate layer. The first conductive layer can include the active layer and the second conductive layer can include the gate layer. In some aspects, the first capacitor electrode can include the source drain layer and the second capacitor electrode can include a conductive material that includes the same material as the gate layer. In some aspects, the first capacitor electrode can include the active layer and the second capacitor electrode can include a conductive material that includes the same material as the gate layer. The device can include a second display element and at least one interferometric optical mask structure disposed between the first display element and the second display element. The at least one switch can be disposed at least partially between the optical mask structure and the first display element.

Another innovative aspect of the subject matter described in this disclosure can be implemented in a method of forming a device. The method includes forming a display element having a first electrode and a second electrode with the second electrode being movable relative to the first electrode, forming at least one switch configured to control a flow of charge between a source and the first display element, forming a storage capacitor having a first capacitor electrode and a second capacitor electrode, and electrically connecting the first capacitor electrode to the first electrode of the display element. The at least one switch includes a first conductive layer, a second conductive layer, and a source/drain layer electrically connected to the first electrode of the first display element. One of the first capacitor electrode and the second capacitor electrode includes one of the first conductive layer, the second conductive layer, and the source/drain of the at least one switch. In some aspects, forming the at least one switch can include forming a thin-film transistor having an active layer and a gate layer. The first conductive layer can include the active layer and the second conductive layer includes the gate layer. In some aspects, the first capacitor electrode can include the source/drain layer and the second capacitor electrode can include a conductive material that includes the same material as the gate layer. The first capacitor electrode can include the active layer and the second capacitor electrode can include a conductive material that includes the same material as the gate layer. In some aspects, the method can include providing a second display element and providing at least one interferometic optical mask structure between the first display element and the second display element. The at least one switch can be disposed at least partially between the optical mask structure and the first display element.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows a circuit diagram for one example of an active-matrix IMOD array.

FIG. 9B shows a simplified diagram of a portion of the example circuit of FIG. 9A.

FIG. 10 shows a schematic plan view of one example of an active-matrix array of display elements.

FIGS. 11A-11O show examples of cross-sectional schematic illustrations of various stages in a method of making the active-matrix array of FIG. 10 taken along the line 11-11.

FIG. 12 shows a cross-sectional view of an example of one display element of an active-matrix array.

FIG. 13A shows a schematic plan view of an example of an active-matrix array of display elements.

FIG. 13B shows a cross-sectional view of the active-matrix array of FIG. 13A taken along the line 13-13.

FIG. 14 shows an example of a flow diagram illustrating a method of forming a device.

FIGS. 15A and 15B show cross-sectional views of examples of one display element in an active-matrix array of display elements having an associated storage capacitor integrated at least in part with a thin-film transistor.

FIGS. 16A and 16B system block diagrams illustrating a display device that includes a plurality of interferometric modulators.

Like reference numbers and designations in the various drawings indicate like elements, which may have certain structural or characteristic differences according to certain implementations.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

In certain implementations, active-matrix EMS devices including at least one storage capacitor are provided. As used herein, the term “active-matrix” can refer to an EMS device in which each pixel, sub-pixel, or element of the device is individually controlled using an active switch, such as a thin-film transistor (TFT). The EMS device can include an optical stack disposed over a substrate and a movable reflective membrane (such as a mechanical layer adjacent a reflective layer) positioned over the optical stack to define a gap. The optical stack can include a stationary electrode and one or more dielectric layers. The mechanical layer can include an electrode and is movable within the gap in response to a voltage applied between the mechanical layer and the stationary electrode. For example, a movable electrode can be formed from a portion of the mechanical layer and/or coupled to the mechanical layer, and a voltage difference between the movable electrode and the stationary electrode can be used to generate an electrostatic force that can move the mechanical layer.

In some implementations, to improve electrical and/or optical performance, the EMS device can include one or more storage capacitors and an active switch formed at least partially in an optically non-active region of the device. For example, including an integrated storage capacitor can increase a capacitance associated with a pixel, thereby reducing pixel leakage, reducing drive voltage and/or improving an image refresh of the display. The storage capacitor can include a first plate or layer, a second plate or layer, and a spacer layer, for example, a dielectric layer, disposed between the first and second layers. In some implementations, the first and second layers and the spacer layer of the storage capacitor are formed from a multi-layer black mask structure or interferometric optical mask structure used to absorb light in optically non-active regions of the device. Using one or more layers of a multi-layer optical mask structure to form the storage capacitor can improve the integration of the pixel array, thereby reducing a pixel array footprint. In some implementations, an active switch is also formed over the optical mask structure to further enhance display integration.

Particular implementations of the subject matter described in this disclosure can be implemented to realize one or more of the following potential advantages. For example, some implementations described in this disclosure reduce the drive voltage of a display and/or reduce the impacts of pixel current leakage relative to certain other configurations of displays, such as other active-matrix displays omitting a storage capacitor. Furthermore, some implementations improve an image refresh rate of a display compared to active-matrix displays without a storage capacitor. Moreover, some implementations improve integration of components of a display, thereby allowing the display to be fabricated using a smaller die area compared to designs where a storage capacitor is added without using layers simultaneously for one or more capacitor electrodes as well as other electrical or optical functions. Additionally, some implementations can be used to increase a capacitance associated with pixels of a display. Furthermore, some implementations can be used to reduce fabrication complexity by using layers used in forming pixels to form a storage capacitor. Additionally, some implementations can be used to reduce the power consumption of an array and/or otherwise improve the performance of the array. In this way, implementations described herein can improve the affects of charge leakage on the refresh rate, power consumption, and color variation of a display device without negatively impacting the device's fill factor as compared to other devices that do not include a storage capacitor to offset charge leakage effects.

An example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent display elements or interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

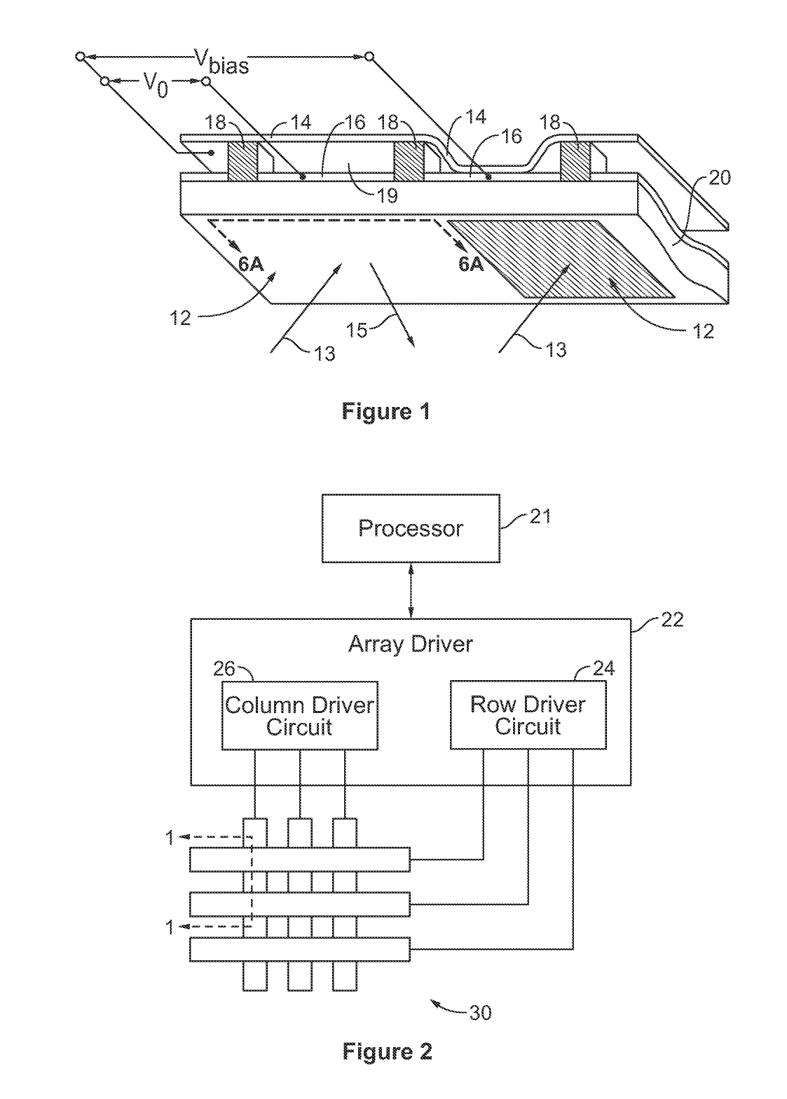

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

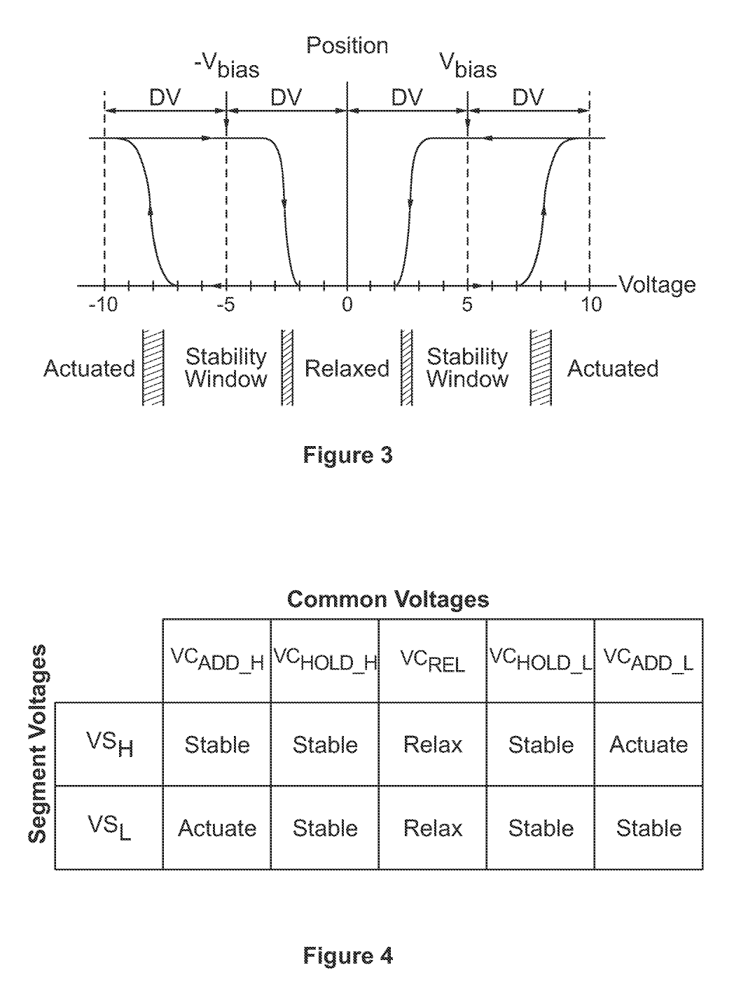

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or minor, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

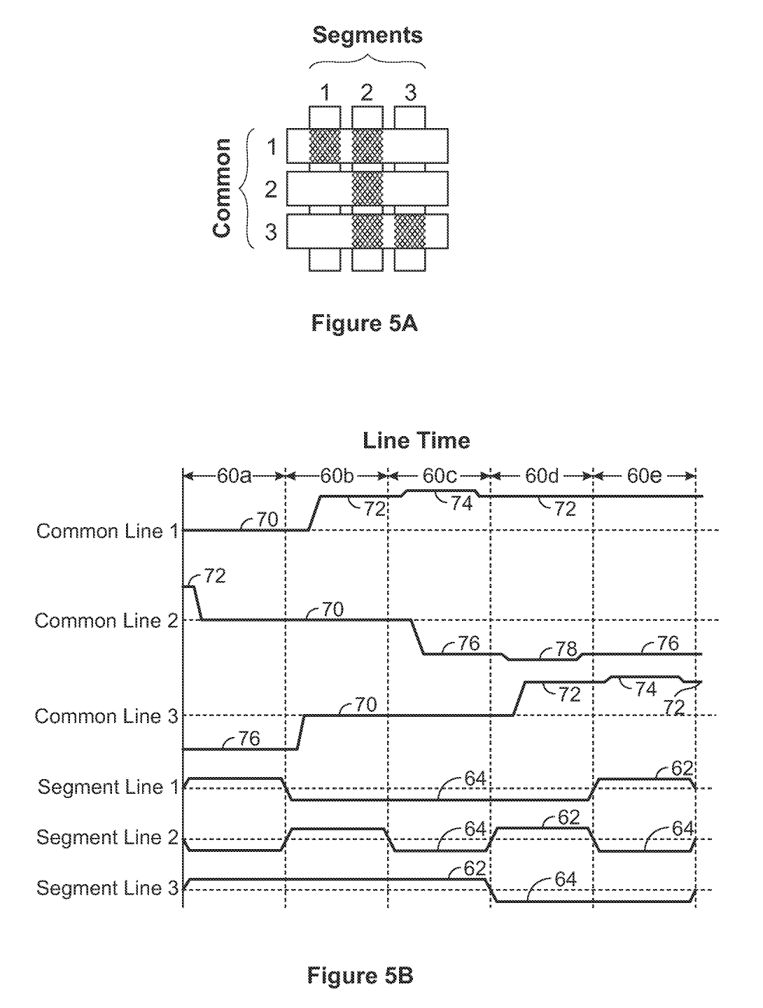

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

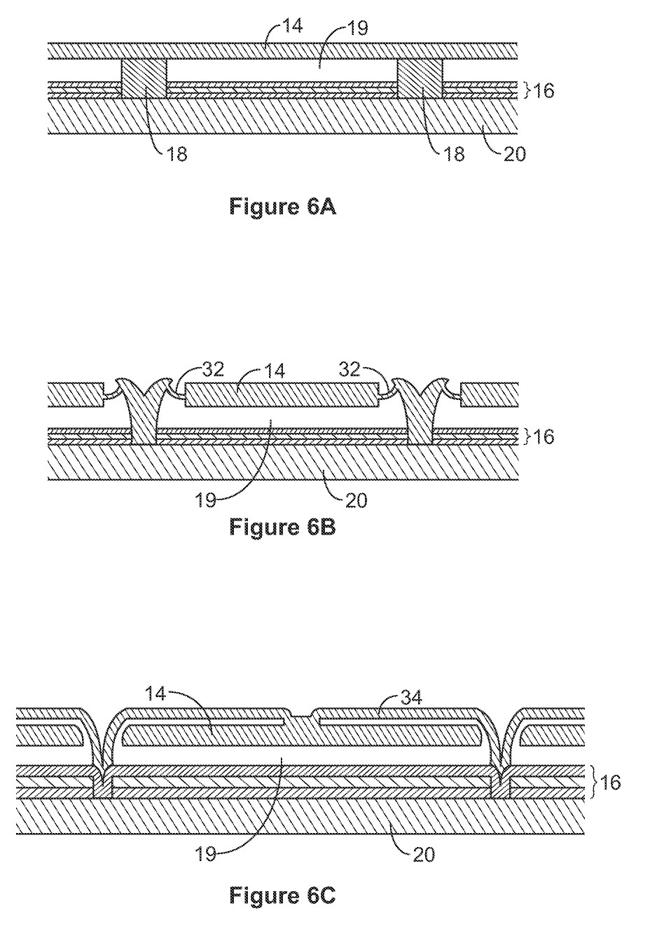

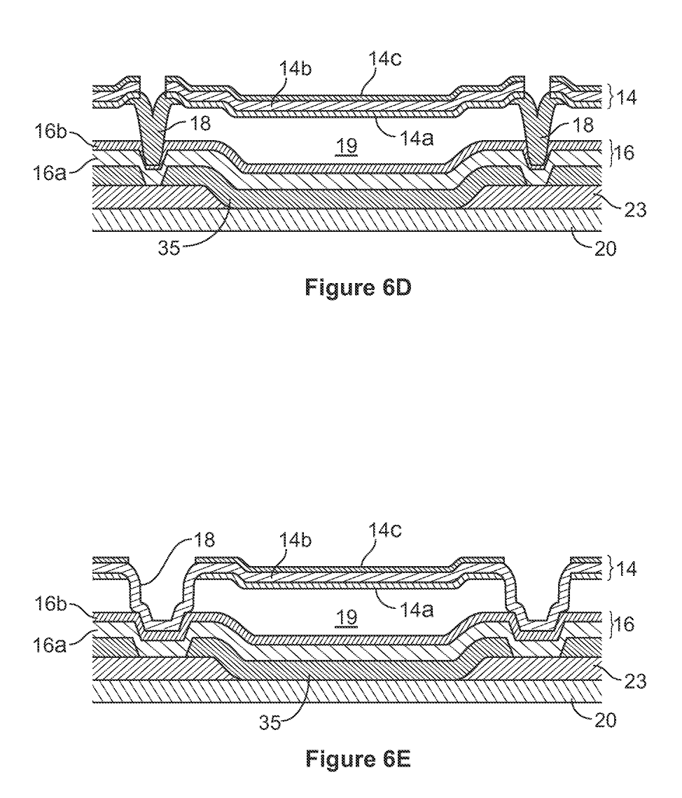

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

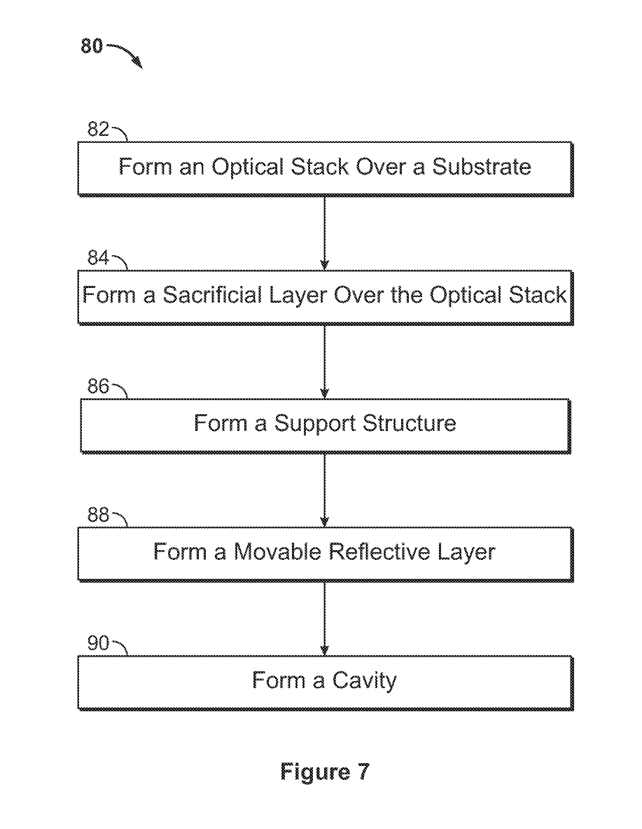

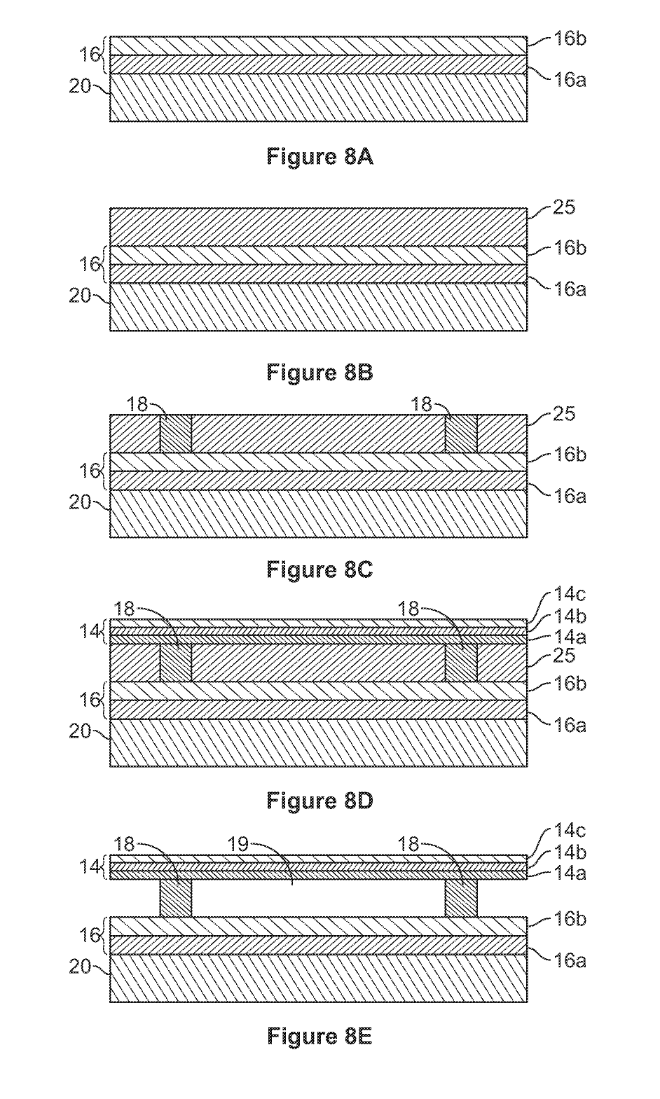

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

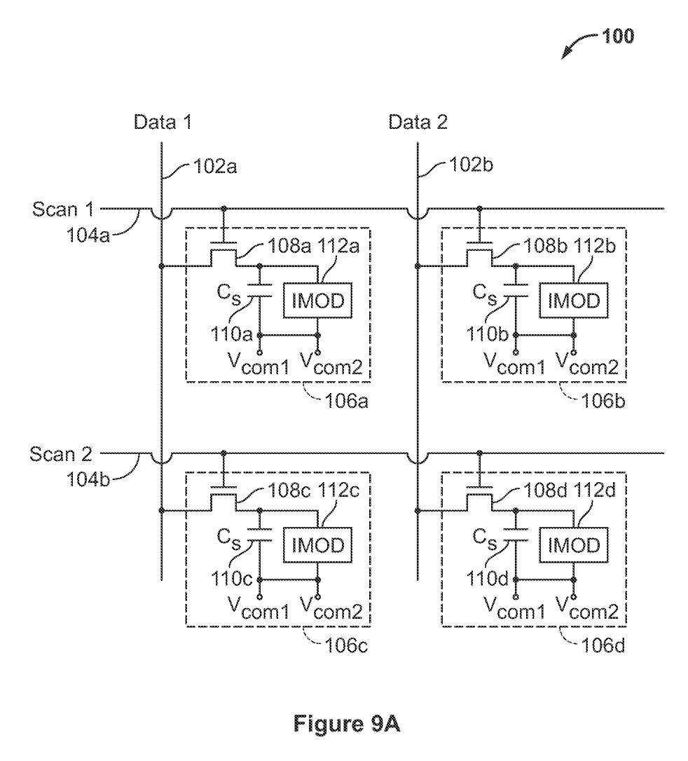

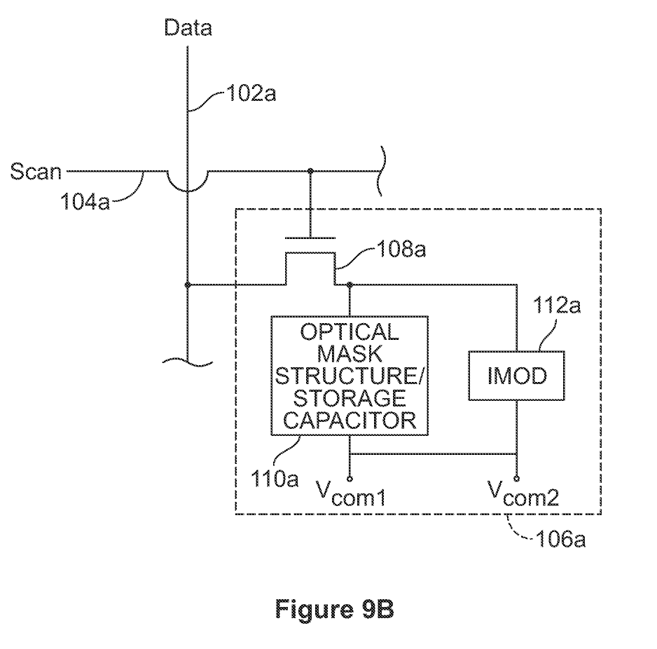

FIG. 9A shows a circuit diagram for one example of an active-matrix IMOD array 100. The illustrated IMOD array 100 includes a first data line 102a, a second data line 102b, a first scan line 104a, a second scan line 104b, a first pixel 106a, a second pixel 106b, a third pixel 106c and a fourth pixel 106d. Although the IMOD array 100 is illustrated as including four pixels 106 for clarity of the illustration, implementations of the IMOD array 100 can include additional pixels, including, for example, pixels of different colors and/or hundreds or thousands, or even millions, of pixels.

In the example illustrated in FIG. 9A, each of the first to fourth pixels 106 includes a thin-film transistor (TFT) 108, a storage capacitor 110 and an IMOD element 112. For example, the first pixel 106a includes a first TFT 108a, a first storage capacitor 110a and a first IMOD element 112a. Similarly, the second pixel 106b includes a second TFT 108b, a second storage capacitor 110b and a second IMOD element 112b. Likewise, the third pixel 106c includes a third TFT 108c, a third storage capacitor 110c and a third IMOD element 112c. Furthermore, the fourth pixel 106d includes a fourth TFT 108d, a fourth storage capacitor 110d and a fourth IMOD element 112d.

In this implementation, the first TFT 108a includes a source electrically coupled to the first data line 102a, a gate electrically coupled to the first scan line 104a and a drain electrically coupled to a first plate of the first storage capacitor 110a and to a first electrode of the first IMOD element 112a. The second TFT 108b includes a source electrically coupled to the second data line 102b, a gate electrically coupled to the first scan line 104a and a drain electrically coupled to a first plate of the second storage capacitor 110b and to a first electrode of the second IMOD element 112b. The third TFT 108c includes a source electrically coupled to the first data line 102a, a gate electrically coupled to the second scan line 104b and a drain electrically coupled to a first plate of the third storage capacitor 110c and to a first electrode of the third IMOD element 112c. The fourth TFT 108d includes a source electrically coupled to the second data line 102b, a gate electrically coupled to the second scan line 104b and a drain electrically coupled to a first plate of the fourth storage capacitor 110d and to a first electrode of the fourth IMOD element 112d.

In the implementation schematically illustrated in FIG. 9A, the first to fourth storage capacitors 110a, 110b, 110c and 110d each include a second plate or layer electrically connected to a first common voltage reference V_{COM1}, which can be, for example, a ground voltage. Additionally, the first to fourth IMOD elements 112a, 112b, 112c and 112d are each electrically coupled to a second common voltage reference V_{COM2}, which can be, for example, a ground voltage. In some implementations, a second electrode of each of the first to fourth IMOD elements 112a, 112b, 112c and 112d is electrically coupled to the second common voltage reference V_{COM2}. However, other implementations are possible. For example, the second ends of the first and second capacitors 110a and 110b can be electrically connected to the first common voltage reference and the second ends of the third and fourth capacitors 110c and 110d can be electrically connected to the second common voltage reference or a third common voltage reference. Additionally, the second electrodes of the first and second IMODs 112a and 112b can be electrically connected to the second common voltage reference and the second electrodes of the third and fourth IMODs 112c and 112d can be electrically connected to a third or fourth common voltage reference. In some implementations, the first electrode of each of the first to fourth IMOD elements 112a, 112b, 112c and 112d is a movable electrode and the second electrode of each of the first to fourth IMOD elements 112a, 112b, 112c and 112d is a stationary electrode.

In some implementations, the storage capacitors 110a, 110b, 110c and 110d illustrated in FIG. 9A can have a capacitance selected to be in the range of about 10 fF to about 1,000 fF, for example, about 60 fF. The capacitance of the storage capacitors 110a, 110b, 110c and 110d also can be selected relative to the capacitance of the IMOD elements 112a, 112b, 112c and 112d. For example, in some implementations, each storage capacitor has a capacitance that is about 1 times to about 3 times the capacitance of an associated IMOD element when the IMOD element is in an unactuated or undriven state. A person having ordinary skill in the art will readily understand that capacitance values can depend on many factors, such as air gap, pixel size, drive voltage requirement, power consumption, etc.

The first and second data lines 102a and 102b and the first and second scan lines 104a and 104b can be used to write image data to the IMOD array 100 of FIG. 9A. For example, a signal provided on the first scan line 104a can be used to address a first row of the IMOD array 100 associated with the first and second pixels 106a and 106b. A signal provided on the second scan line 104b can be used to address a second row of the IMOD array 100 associated with the third and fourth pixels 106c and 106d. Additionally, the voltage provided to the first and second data lines 102a and 102b can be controlled so as to set the state of the IMOD elements 112 in the selected row. For example, when addressing a given row, pixels 106 in the addressed row that are to be actuated can be exposed to a voltage difference between the data line and the common voltage references V_{COM1} and V_{COM2} suitable for actuation, and pixels 106 that are to be relaxed (or unactuated) can be exposed to a voltage difference between the data line and the common voltage references V_{COM1} and V_{COM2} suitable to cause the mechanical layer of the IMOD elements 112 to be moved to a relaxed state. In some implementations, the actuation voltage is in the range of about 10 V to about 16 V, for example, about 12 V, and the relaxation voltage is in the range of about 0 V to about 8 V.

Still referring to FIG. 9A, the inclusion of the first to fourth storage capacitors 110a, 110b, 110c and 110d can increase the amount of charge stored for a given amount of voltage across each IMOD element 112. For example, the amount of charge stored on each of the IMOD elements 112a, 112b, 112c and 112d can be equal to about V_{IMOD}*(C_{IMOD}+C_{S}), where V_{IMOD} is the voltage difference between the first and second electrodes of the IMOD element 112, C_{IMOD} is the capacitance of the IMOD element 112 when the IMOD element 112 is in an unactuated or undriven state which can be assumed to be constant during the time that a pulse is applied to charge both the IMOD element 112 and the storage capacitor 110, and Cₛ is the capacitance of the storage capacitor 110. Including the storage capacitors 110 can increase pixel charge storage and can reduce the impacts of pixel current leakage. For example, charge leakage, such as leakage associated with channel leakage of a thin-film transistor (TFT), can cause the voltage of a pixel 106 to change over time and can lead to a pixel 106 changing state if it is not refreshed at a sufficiently fast rate or if the pixel 106 does not have a sufficient amount of stored charge.

Accordingly, the first to fourth storage capacitors 110a, 110b, 110c and 110d of FIG. 9A can help prevent pixel leakage from changing the voltage across the electrodes of the first to fourth IMOD elements 112a, 112b, 112c and 112d over time, thereby reducing drive voltage and power consumption of the pixel array 100. In this way, the image refresh rate would be improved because the image would require less refresh for a static image because the drive voltage would be maintained. FIG. 9B shows a simplified diagram of a portion of the example circuit of FIG. 9A. As shown in FIG. 9B, and as discussed below, in some implementations, an integrated storage capacitors 110 can be formed from one or more layers of an optical mask structure. For example, each storage capacitor 110 can have a first capacitor electrode and a second capacitor electrode. At least one of the first capacitor electrode and the second capacitor electrode can be formed by a conductive layer of an optical mask structure. For example, an optical mask structure can include two conductive layers that form the storage capacitor or a single layer of the optical mask structure can form a storage capacitor along with another conductive layer that is not part of the optical mask structure.

Referring back to FIG. 9A, using layers of the optical mask structure to form the storage capacitors 110a, 110b, 110c and 110d in all or part can help integrate the design of the pixel array 100, thereby reducing the area (or footprint) of the array when compared to design in which optical mask structures and storage capacitors would require separate real estate or space. Although the pixel array 100 illustrates one configuration suitable for using the storage capacitors 110a, 110b, 110c and 110d, integrated storage capacitors can be used in any suitable pixel array, including, for example, other implementations of active or analog IMOD arrays.

As discussed above, in some implementations an IMOD device can include a multi-layer black mask or optical mask structure formed in an optically inactive region (for example, between pixels or under posts) and configured to absorb ambient or stray light. In this way, the optical mask structure can improve the optical properties of a display device by inhibiting light from being reflected from or transmitted through inactive portions of the display, thereby increasing the contrast ratio. In some implementations, an optical mask structure can also form an integrated storage capacitor. Such an IMOD device can be included in an active-matrix pixel array, and the storage capacitor can be used to improve the performance of the active-matrix pixel array. For example, the storage capacitor can improve image refresh rate of the array and/or reduce drive voltage or power consumption of the array.

The storage capacitor can include one or both of a first conductive layer of the optical mask structure and a second conductive layer of the optical mask structure. The first conductive layer can be partially reflective, partially transmissive, and partially absorptive, and the second conductive layer can be highly reflective. For example, the second conductive layer can have a higher reflectivity than the first conductive layer The storage capacitor can also include a spacer layer, for example, one or more dielectric layers, disposed between the first conductive layer and the second conductive layer to electrically isolate the two conductive layers of the optical mask structure. In this way, can function as an interferometric stack structure. Using one or more layers of a multi-layer optical mask structure to form the storage capacitor can improve the integration of the pixel array, thereby reducing a footprint of the pixel array.

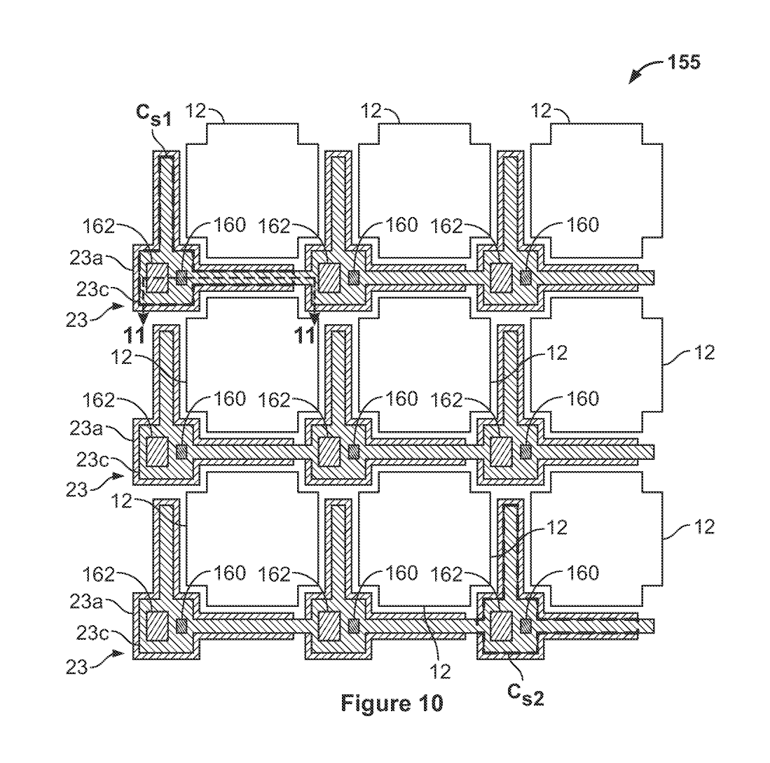

FIG. 10 shows a schematic plan view of one example of an active-matrix array 155 of display elements 12. In some implementations, the display elements or pixels 12 can include IMOD display elements. The active-matrix array 155 also includes thin-film transistors (TFTs) 162 and vias 160. The array 155 further includes a multi-layer optical mask structure 23 including a first conductive layer 23a, a second conductive layer 23c disposed over the first conductive layer 23a (disposed nearer to the viewer in FIG. 10 than the first conductive layer 23a), and a spacer layer (not seen in FIG. 10 but shown in 11B-11O) disposed between the first conductive layer 23a and the second conductive layer 23c. As shown, the optical mask structure 23 can be disposed at least partially between adjacent display elements 12.

Although not illustrated in FIG. 10 for clarity, the array 155 can include other structures. Also, the illustrated display elements 12 have been arranged in an array, and can be representative of a much larger array of display elements similarly configured. Each of the display elements 12 in this example are associated with a TFT 162 and a via 160, which can be used for electrically connecting the TFT 162 to an electrode associated with the display element 12.

The multi-layer optical mask structure 23 can be utilized used to form storage capacitors for each of the display elements 12 of the array 155. For example, storage capacitors can be formed in regions of the array 155 in which the first conductive layer 23a, the spacer layer 23b and the second conductive layer 23c overlap. For example, in regions in which each of these layers have been provided, the first and second conductive layers 23a and 23c can operate as electrodes, plates or layers of a storage capacitor, and the spacer layer 23b can electrically isolate these electrodes, plates or layers from one another. For example, a first storage capacitor C_{S1} has been illustrated using dark dashed lines and is associated with the upper-left display element 12 of the array 155, and a second storage capacitor C_{S2} has been illustrated using dark dashed lines and is associated with the bottom-right display element 12 of the array 155. As shown in FIG. 10, in some implementations the first storage capacitor C_{S1} and second storage capacitor C_{S2} can be generally L-shaped. However, a person having ordinary skill in the art will readily appreciate that the first storage capacitor C_{S1} and second storage capacitor C_{S2} can be differently shaped in different implementations. As discussed below, each storage capacitor formed by an optical mask structure 23 can be electrically coupled to a display element 12 and at least one switch, for example, a TFT, configured to control a flow of charge between a source and the associated display element 12.

Although FIG. 10 illustrates one example of an active-matrix array, other configurations are possible. For example, in some implementations, the patterning of the first and second conductive layers 23a and 23c is reversed. Additionally, although the spacer layer 23b is illustrated as having the same pattern as the second conductive layer 23c, the spacer layer 23b can be configured to have other patterns.

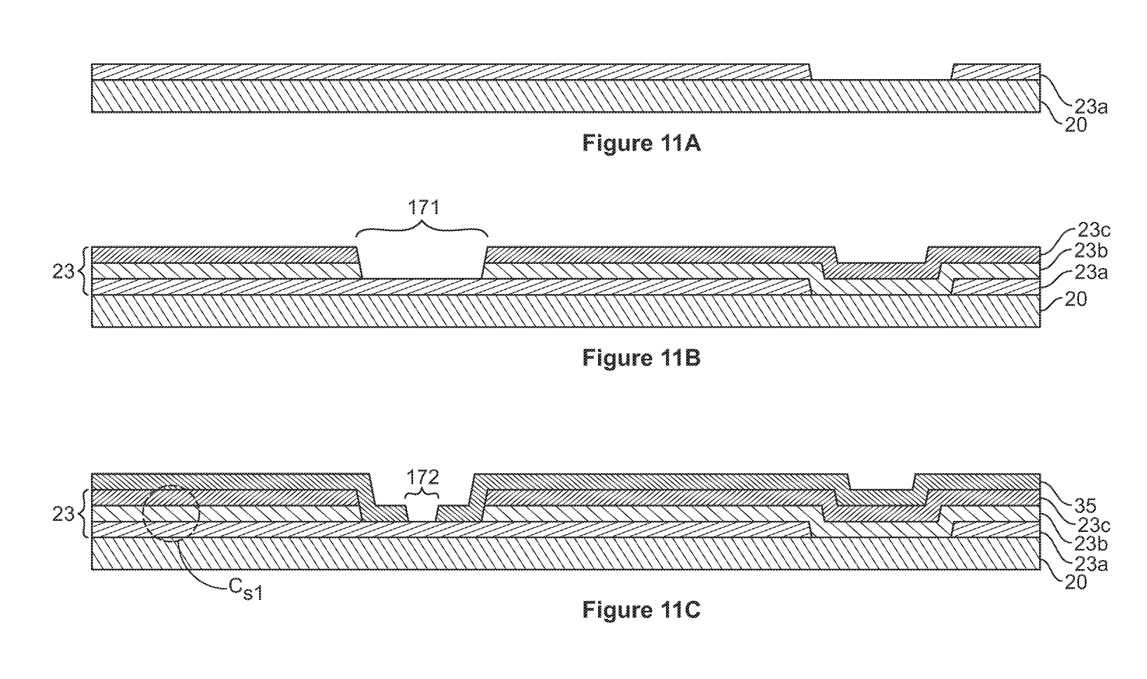

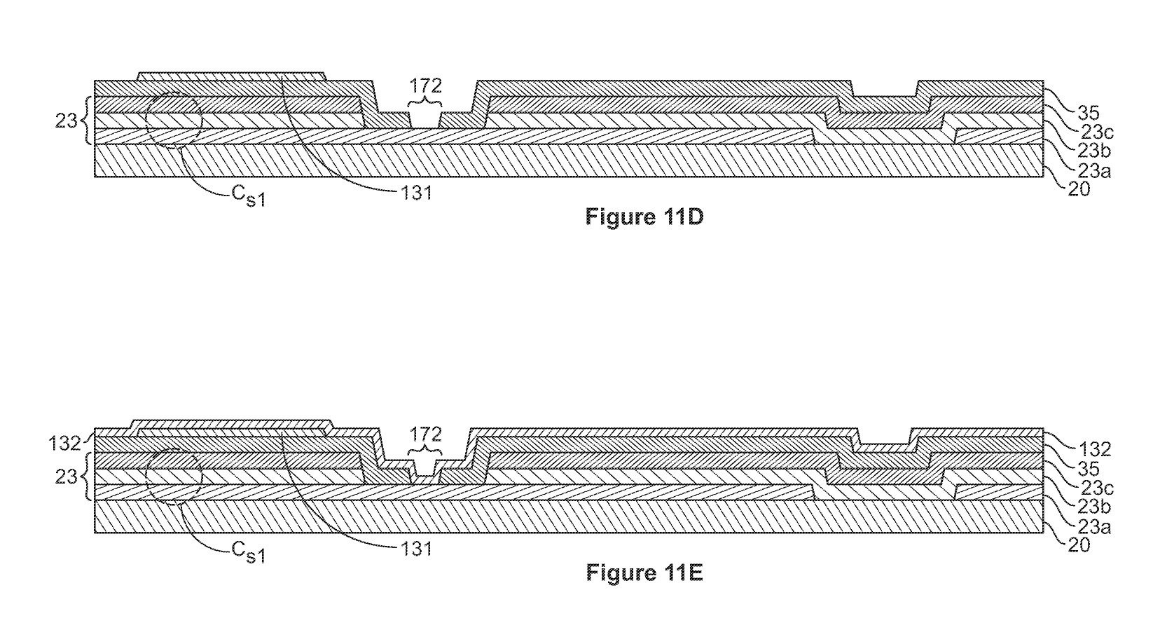

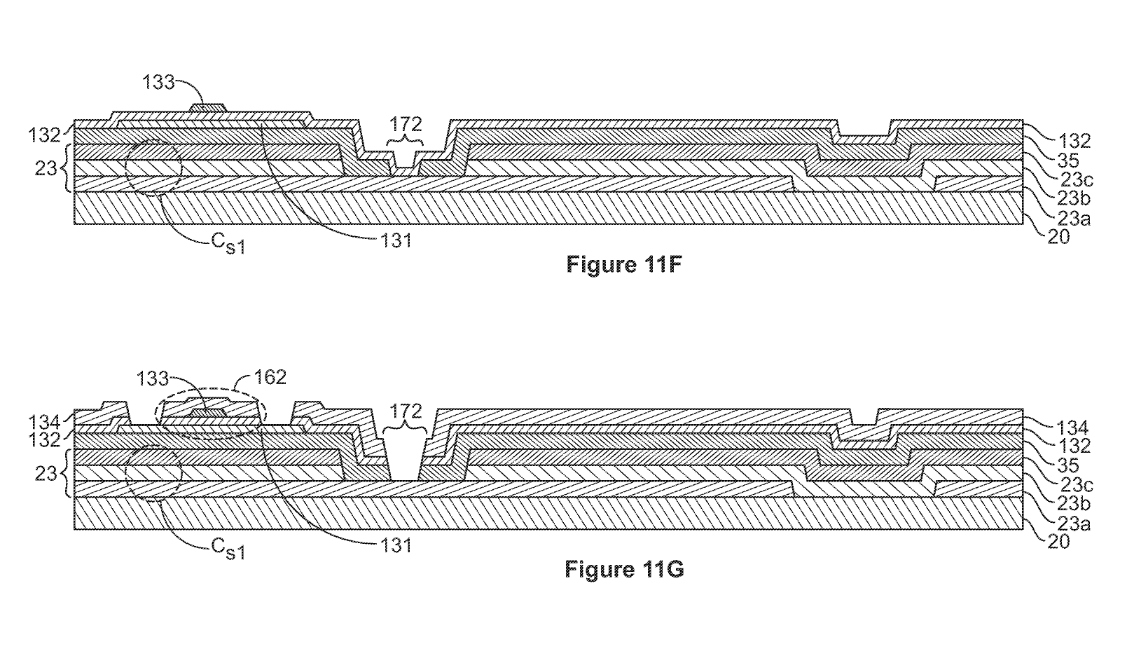

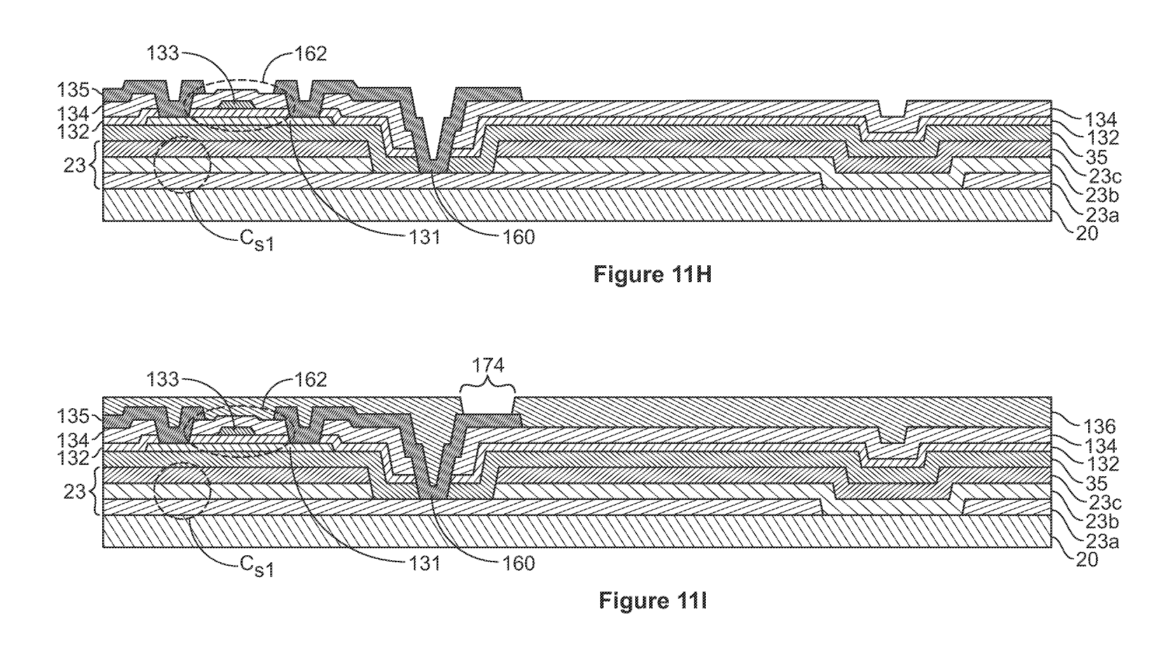

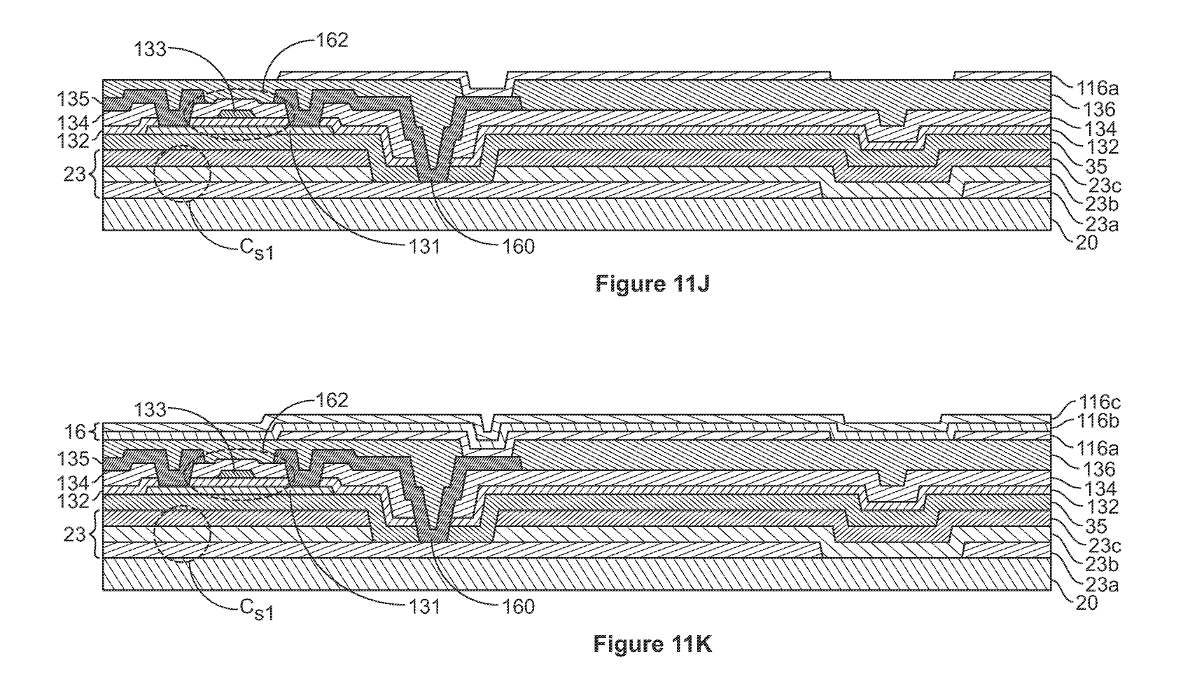

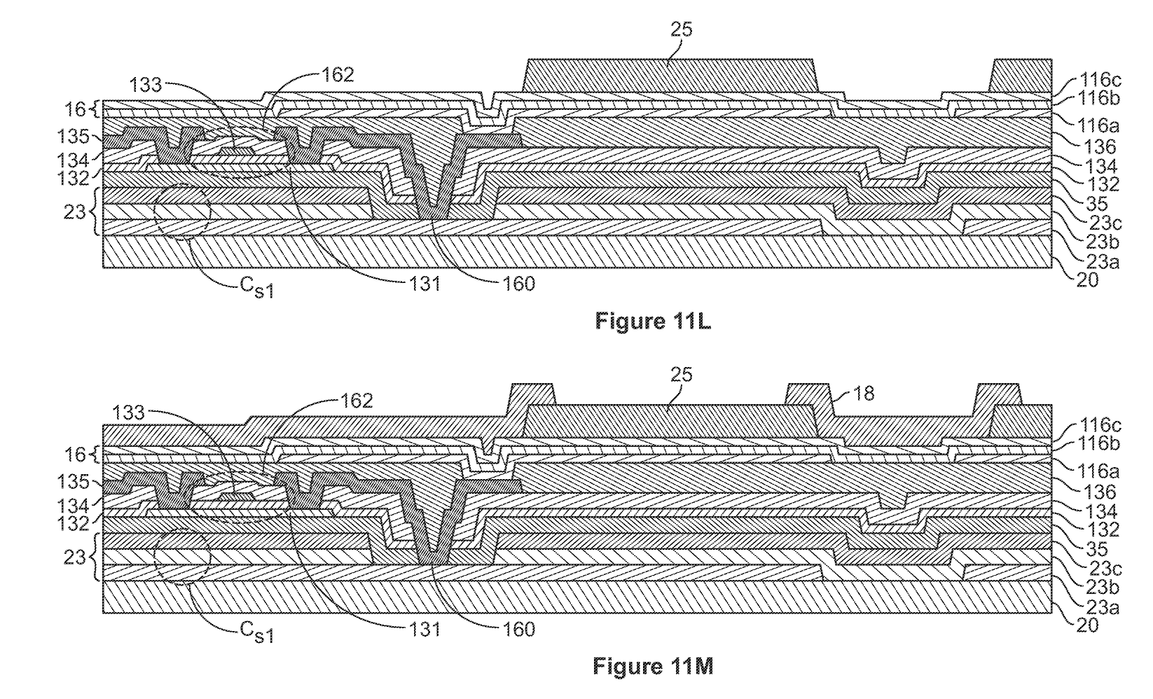

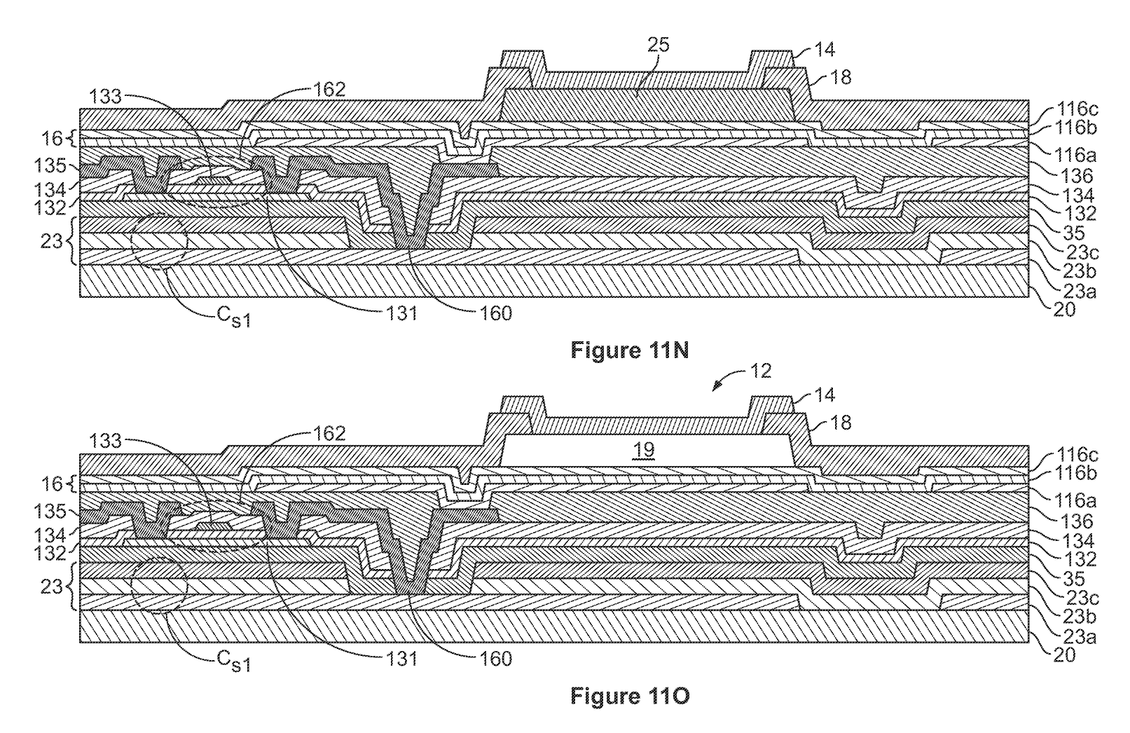

FIGS. 11A-11O show examples of cross-sectional schematic illustrations of various stages in a method of making the active-matrix array 155 of FIG. 10 taken along the line 11-11. While particular parts and steps are described as suitable for fabricating certain implementations of an array, for other implementations, different parts and steps, and materials can be used, or parts can be modified, omitted, or added.

In FIGS. 11A and 11B, an optical mask structure 23 has been provided and patterned on a substrate 20. The substrate 20 can include glass, plastic or any transparent polymeric material which permits light to pass through the substrate 20. The illustrated optical mask structure 23 is a multi-layer structure including a first conductive layer 23a, a spacer layer 23b and a second conductive layer 23c. The first conductive layer 23a, the second conductive layer 23c and the spacer layer 23b can include any suitable materials. At least one layer of the optical mask structure 23 can be configured to absorb ambient or stray light in optically inactive regions of the array. However, each layer of the optical mask structure 23 need not absorb light.

In some implementations, the first conductive layer 23a can include a partially reflective, partially transmissive, and partially absorptive material, for example, MoCr, and can have a thickness in the range of about 30-80 Å. The spacer layer 23b can include a non-conductive or dielectric material, for example, SiO₂, having a thickness in the range of about 500-1000 Å. The second conductive layer 23c can include a reflective material, for example, Al or Mo, and can have a thickness in the range of about 500-6000 Å. In some implementations, the reflective second conductive layer 23c has a higher reflectance than the first conductive layer 23a and the second conductive layer 23c has an absorption coefficient that is lower than the first conductive layer 23a. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer.

Part or all of the optical mask structure 23 can be used to form the storage capacitor Cₛ₁. For example, in regions in which each of the first, second and third layers 23a, 23b and 23c of the optical mask structure 23 overlap, the first and second conductive layers 23a and 23c can operate as plates or electrodes of the storage capacitor Cₛ₁, and the spacer layer 23b can electrically isolate the plates or electrodes of the storage capacitor Cₛ₁.

The first and second conductive layers 23a and 23c can be electrically connected to the desired electrical potentials to operate the optical mask structure 23 as a storage capacitor Cₛ₁. For example, the second conductive layer 23c can be electrically connected to a reference voltage such as ground, and the first conductive layer 23a can be electrically connected to an electrode of a display element. To aid in physically and electrically connecting the first conductive layer 23a to one or more subsequently deposited layers, an opening 171 has been provided through a portion of the dielectric layer 23b and the second conductive layer 23c.

FIG. 11C illustrates providing a spacer or buffer layer 35. The buffer layer 35 can include, for example, SiO₂, SiN, SiON, tetraethyl orthosilicate (TEOS), and/or other suitable dielectric material(s). In some implementations, the thickness of the buffer layer 35 is in the range of about 1,000-10,000 Å, however, the buffer layer 35 can have a variety of thicknesses depending on desired optical properties. A portion of the buffer layer 35 can be removed over the first conductive layer 23a (“over” here referring to the side of the first conductive layer 23a opposite the substrate 20) so as to permit the formation of a via for electrically connecting the storage capacitor Cₛ₁ of the optical mask structure 23 to a TFT and an electrode of a display element, as will be described in further detail below. For example, the buffer layer 35 has been patterned, removing a portion of the buffer layer 35, to form an opening 172 through which a subsequently deposited conductor can contact the first conductive layer 23a. In this way, the storage capacitor Cₛ₁ of the optical mask structure 23 can be electrically connected to another structure disposed over the optical mask structure. For example, the storage capacitor Cₛ₁ can be electrically coupled to a TFT and a stationary electrode of a display element, such as an IMOD display element.

In the illustrated configuration, the opening 172 in the buffer layer 35 is formed within the opening 171 of the spacer layer 23b and second conductive layer 23c of the optical mask structure 23. Configuring the opening 172 to be smaller than the opening 171 allows the buffer layer 35 to electrically isolate the second conductive layer 23c from a subsequently deposited conductive layer.

In FIG. 11D, an active layer 131 has been provided and patterned on the buffer layer 35. In some implementations, the active layer 131 includes silicon (Si) and/or any other semiconductor material suitable for forming a channel region of a TFT device. The active layer 131 can be doped using n-type or p-type dopants, including, for example, boron (B), phosphorous (P), or arsenic (As) to achieve the desired channel conductivity. The doping can be accomplished using any suitable process, including, for example, ion implantation.

In FIG. 11E, a gate dielectric layer 132 has been provided over the device of FIG. 11D. In FIG. 11F, a gate layer 133 has been provided over the gate dielectric layer 132 to form a gate structure of the TFT 162. In some implementations, the gate dielectric layer 132 and the gate layer 133 can include silicon dioxide (SiO₂) and, for example, molybdenum respectively. As illustrated in FIGS. 11E and 11F, the gate dielectric layer 132 can be patterned such that the opening 172 extends through both the buffer layer 35 and the gate dielectric layer 132 so as to allow a subsequently deposited layer to physically and electrically contact the first conductive layer 23a of the optical mask structure 23.

In FIG. 11G, a spacer dielectric layer 134 is formed over the gate layer 133. The spacer dielectric layer 134 can be used to electrically isolate the gate layer 133 formed in FIG. 11F from subsequently deposited conductive layers and/or to protect the gate layer 133 during processing. In some implementations, the spacer dielectric layer 134 includes silicon dioxide (SiO₂). The spacer dielectric layer 134 and gate dielectric layer 132 can be patterned to include openings, such as openings that can be used to contact the active layer 131. Additionally, the spacer dielectric layer 134 can be patterned such that the opening 172 also extends through the spacer dielectric layer 134.

FIG. 11H illustrates forming a source/drain conductive layer or transistor contact layer 135 over the spacer dielectric layer 134. The source/drain conductive layer 135 can include any suitable conductor, such as aluminum (Al), and can be patterned to form a desired metal connectivity for the sources and drains of the TFT 162. In the illustrated configuration, the source/drain conductive layer 135 has been formed over the opening 172 of FIG. 11G to form a via 160. The via 160 can be used to provide electrical connectivity between the TFT 162, the storage capacitor Cₛ₁ of the optical mask structure 23, and an electrode of a subsequently deposited mechanical layer of a display element. In the illustrated configuration, the via 160 is used to electrically connect the source/drain conductive layer 135 to the first conductive layer 23a of the optical mask structure 23. However, as discussed below, the via 160 can be configured in other ways, such as to provide a connection between the source/drain conductive layer 135 and the second conductive layer 23c, or between a conductive layer of the optical mask structure 23 and an electrode of a display element.

In FIG. 11I a planarization layer 136 has been formed over the spacer dielectric layer 134 and the source/drain conductive layer 135. The planarization layer 136 can be used as a surface over which a display element can be formed, and in some implementations can include silicon dioxide (SiO₂). As illustrated in FIG. 11I, the planarization layer 136 can include an opening 174 which can be used to allow a subsequently formed electrode of a display element, for example, a stationary electrode, to electrically contact the TFT 162 and the storage capacitor Cₛ₁ of the optical mask structure 23 using the source/drain conductive layer 135 and the via 160.

Reference will now be made to FIGS. 11J and 11K, which illustrate forming an optical stack 16 over the planarization layer 136. The optical stack 16 can include a stationary electrode 116a, a first dielectric layer 116b and a second dielectric layer 116c.

FIG. 11J shows the formation of the stationary electrode 116a. As illustrated, the stationary electrode 116a can be patterned to provide electrical isolation between pixels or display elements of the array. The stationary electrode 116a also can be configured to contact the source/drain conductive layer 135 over the opening 174 of FIG. 11I, thereby electrically connecting the stationary electrode 116a to the associated TFT 162 and to the storage capacitor Cₛ₁ of the optical mask structure 23. In some implementations, the stationary electrode 116a can include an optically partially reflective, partially transmissive, and partially absorptive electrical conductor such as molybdenum-chromium (MoCr).

FIG. 11K illustrates forming the first dielectric layer 116b over the stationary electrode 116a and forming the second dielectric layer 116c over the first dielectric layer 116b. In some implementations, the first dielectric layer 116b can include silicon dioxide (SiO₂) and/or silicon oxynitride (SiON), and the second dielectric layer 116c can include aluminum trioxide (Al₂O₃). Although the optical stack 16 includes two dielectric layers in the illustrated configuration, in some implementations the optical stack 16 can include more or fewer dielectric layers and/or can be modified to include other layers (for example, one or more non-dielectric layers). Additionally, although the first and second dielectric layer 116b and 116c are shown as having the same pattern, other configurations are possible.

Although line 11-11 in FIG. 10 does not extend through the display element 12, the formation of the display element 12 adjacent to the cross-section through line 11-11 of FIG. 10 will now be described with reference to FIGS. 11L-11O. Thus, it will be readily apparent to those skilled in the art that although these figures are characterized as cross-sectional views through the array 155, portions of the array 155, including, for example, portions of the display element 12, that are not part of the cross-section through line 11-11 are illustrated to show the relationship between the TFT 162, optical mask structure 23, and display element 12. Further, for the sake of convenience, the TFT 162 and other components are not illustrated to scale. For example, the TFT 162 is shown larger relative to the width of the display element 162 in order to properly illustrate the TFT 162 and the formation of the array 155.

FIG. 11L illustrates providing and patterning a sacrificial layer 25 over the optical stack 16. The sacrificial layer 25 can subsequently be removed or released to form a gap or cavity in the display element. The formation of the sacrificial layer 25 over the optical stack 16 can include a deposition step, as described above. Additionally, the sacrificial layer 25 can be selected to include more than one layer, or include a layer of varying thickness, to aid in the formation of a display device having a multitude of resonant optical gaps between different display elements. For an array if IMOD display elements, each gap size can represent a different reflected color.

FIG. 11M illustrates providing and patterning a support layer over the sacrificial layer 25 to form support posts 18. The support posts 18 can be formed from, for example, silicon dioxide (SiO₂) and/or silicon oxynitride (SiON), and the support layer may be patterned to form the support posts 18 by a variety of techniques, such as using a dry etch including carbon tetraflouride (CF₄) and/or oxygen (O₂). As illustrated in FIG. 11M, in some implementations the support posts 18 can be positioned at pixel corners.

FIG. 11N illustrates providing and patterning a movable or mechanical layer 14 of the display element over the sacrificial layer 25. Although the mechanical layer 14 is illustrated as a single layer in this configuration, in some implementations the mechanical layer 14 can be a multi-layer structure, as was described earlier. The mechanical layer 14 has been patterned over support posts 18 to aid in forming columns of the array.

FIG. 11O illustrates the display element 12 after removal of the sacrificial layer 25 of FIG. 11N to form a gap 19. The sacrificial layer 25 may be removed at this point using a variety of methods, as described earlier.

The array illustrated in FIG. 11O can be used in a high fill-factor pixel array. For example, with reference to FIGS. 10 and 110, each pixel or display element 12 of the pixel array 155 includes a storage capacitor Cₛ₁ formed from the optical mask structure 23, thereby improving the integration of the design. Additionally, each TFT 162 has been formed over the optical mask structure 23 and an integrated via 160 has been used to provide electrical connectivity between the storage capacitor Cₛ₁, TFT 162 and an electrode associated with each of the pixels or display elements 12.

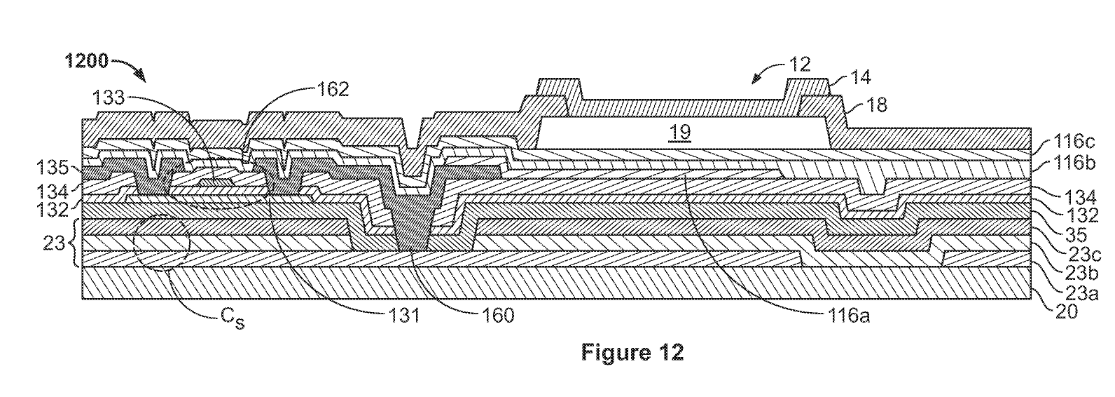

FIG. 12 shows a cross-sectional view of an example of one display element 12 of an active-matrix array 1200. FIG. 12 illustrates a portion of one display element 12 that is part of the array 1200. As with FIGS. 11L-11O, the display element 12 would not be visible in the illustrated cross-sectional view but is shown nonetheless to demonstrate the relationship between the storage capacitor Cₛ, the TFT 162, and the display element 12. As with the active-matrix array of FIGS. 10 and 11A-11O, the array 1200 can include a TFT 162 that is electrically coupled by a via 160 to an associated storage capacitor Cₛ formed by an optical mask structure 23. The TFT 162 can also be electrically coupled by the via 160 to a display element 12. In this way, the storage capacitor Cₛ can increase a capacitance associated with the display element 12, thereby reducing pixel leakage, reducing drive voltage and/or improving an image refresh of the array 1200. Further, because the storage capacitor Cₛ can be formed from the optical mask structure 23, the storage capacitor Cₛ can be integrated within the array 1200 without increasing a footprint or area required by the array 1200. That is to say, because the storage capacitor Cₛ is formed by the optical mask structure 23 of the array 1200, additional layers and/or real estate are not required to form the storage capacitor Cₛ.

In contrast to the active-matrix array of FIGS. 10 and 11A-11O, the array 1200 does not include a planarization layer formed beneath the optical stack 16. The optical stack 16 and display element 12 are formed over the non-planarized surfaces of the spacer dielectric layer 134 and transistor contact layer 135. As a result, the array 1200 can be formed with fewer steps and can have a smaller footprint than the array of FIGS. 10 and 11A-11O.

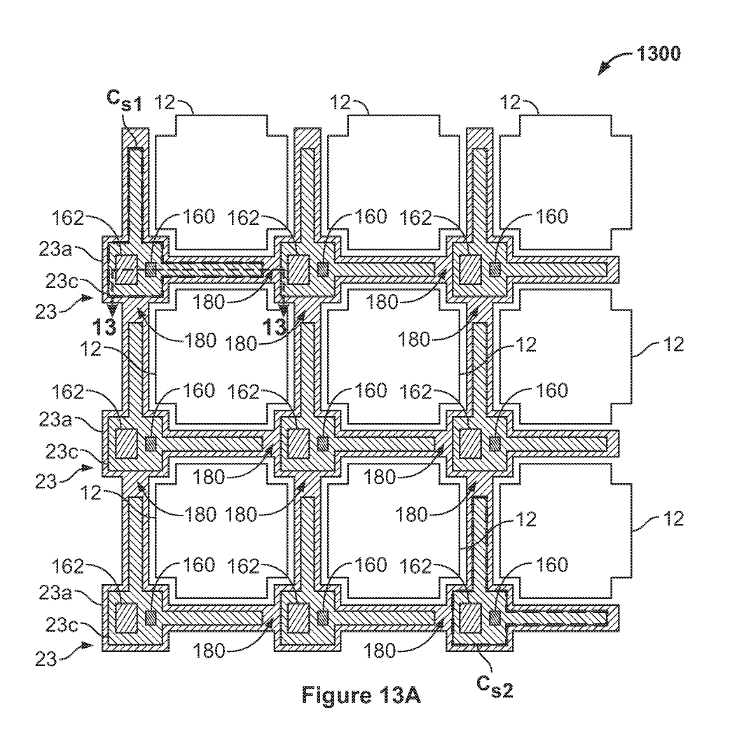

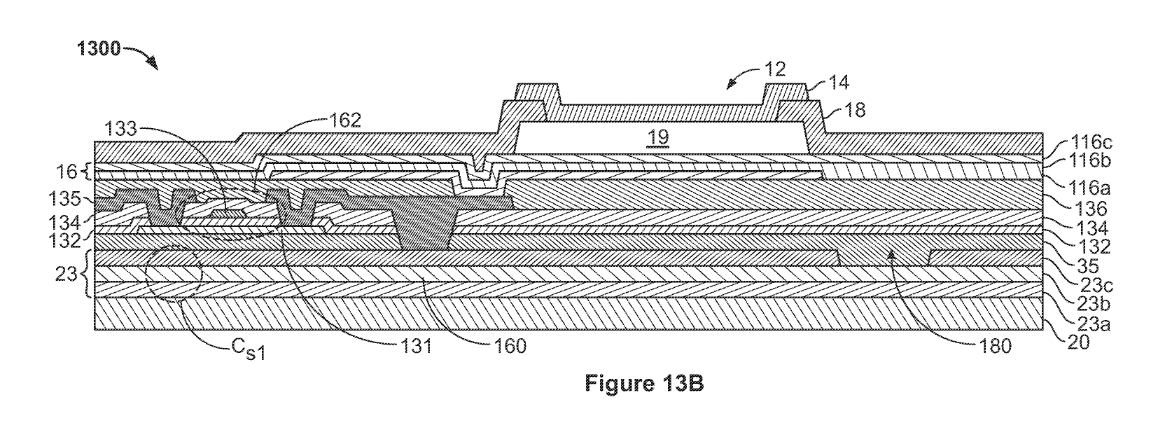

FIG. 13A shows a schematic plan view of an example of an active-matrix array 1300 of display elements 12. FIG. 13B shows a cross-sectional view of the active matrix 1300 of FIG. 13A taken along the line 13-13. As with the array 155 of FIG. 10, in some implementations, the display elements or pixels 12 can include IMOD display elements. The active-matrix array 1300 also includes thin-film transistors (TFTs) 162 and vias 160. The array 155 further includes a multi-layer optical mask structure 23 including a first conductive layer 23a, a second conductive layer 23b disposed over the first conductive layer 23a, and a spacer layer 23b disposed between the first conductive layer 23a and the second conductive layer 23b. As shown, the optical mask structure 23 can be disposed at least partially between adjacent display elements 12.

As shown in FIG. 13A, the first conductive layer 23a can extend continuously between the display elements 12 and the second conductive layer 23c can be patterned to include gaps 180 disposed between portions of the second conductive layer 23c. In this way, the first conductive layer 23a and the second conductive layer 23c of the optical mask structure 23 can form discrete storage capacitors Cₛ that are electrically separated from one another by the gaps 180. In some implementations, the storage capacitors Cₛ can reduce pixel leakage, reduce drive voltage and/or improve an image refresh of the array 1300.

With reference now to FIG. 13B, because the first conductive layer 23a of the illustrated optical mask 23 extends continuously between the display elements 12, the second conductive layer 23c of each storage capacitor Cₛ is be electrically connected to an associated TFT 162 and to an electrode of an associated display element 12 (for example, the stationary electrode 116a of the associated display element 12) so that each discrete storage capacitor Cₛ may be separately connected to a TFT 162. As a result, the vias 160 of the array 1300 electrically connect the second conductive layer 23c of each storage capacitor Cₛ with the associated TFT 162 and stationary electrode 116a of the associated display element 12 and do not pass through the second conductive layer 23c and dielectric layer 23b. In such an implementation, the proximity of the channel in the TFT 162 to the second conductive layer 23c may affect charge propagating inside the channel as compared to the implementations described above with reference to FIGS. 110 and 12. However, by connecting the second conductive layer 23c of each storage capacitor Cₛ with the associated TFT 162, the second conductive layer 23c may extend continuously below the via 160 to decrease the reflectivity of non-display portions of the array 1300 as compared to the implementations of FIGS. 110 and 12.

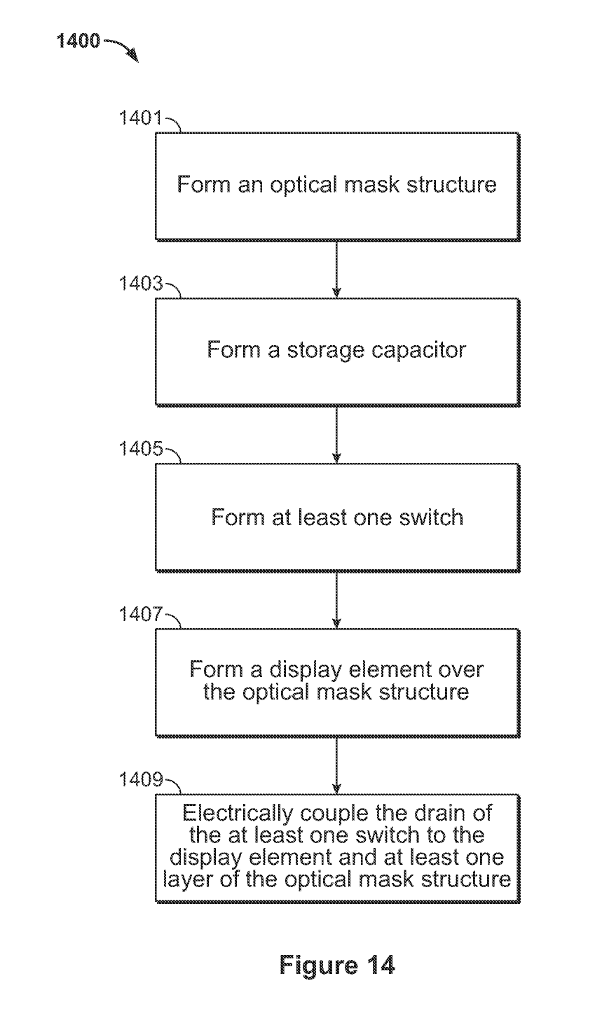

FIG. 14 shows an example of a flow diagram illustrating a method 1400 of forming a device. Block 1401 of the example method 1400 includes forming an optical mask structure. In some implementations, the optical mask structure can be configured to mask an optically non-active portion of the device and can include a partially reflective, partially transmissive, and partially absorptive first conductive layer, a reflective second conductive layer, and a spacer layer disposed between the first and second conductive layers. In some implementations, the second conductive layer has a higher reflectance than the first conductive layer and the second conductive layer has an absorption coefficient that is lower than the first conductive layer. In some implementations, the optical mask structure can be configured similar to the optical mask structures 23 described above with the first and second conductive layers forming at least part of a storage capacitor. The storage capacitor can reduce pixel leakage, reduce drive voltage and/or improve an image refresh of the device.

Block 1403 of the example method 1400 includes forming a storage capacitor. The storage capacitor can include a first capacitor electrode and a second capacitor electrode with one of the first capacitor electrode and the second capacitor electrode including one of the first conductive layer and the second conductive layer of the optical mask structure. That is to say, the first and second conductive layers of the optical mask structure can form one, or both, capacitor electrodes of the storage capacitor.

The example method 1400 also includes forming at least one switch, as shown by block 1405. In some implementations, the at least one switch can be configured to control a flow of charge between a source and a drain. Forming the at least one switch can include forming a thin-film transistor (TFT) similar to the TFT structures 162 described above.

Block 1407 of the example method 1400 includes forming a display element over the optical mask structure. For example, the display element can be formed on a plane that lies above a plane of the optical mask structure, but laterally displaced, such that the display element may be visible even when the optical mask structure is disposed closer to a viewer in a direction normal to the display element. In some implementations, the display element can include a first electrode and a second electrode. For example, the display element can be an interferometric modulator including a movable electrode and a stationary electrode.

Block 1409 of the example method 1400 includes electrically coupling the drain of the at least one switch to the display element and at least one layer of the optical mask structure. In some implementations, the drain can be electrically coupled to the second conductive layer and the first electrode, or the drain can be electrically coupled to the first conductive layer and the first electrode. For example, the drain can be electrically coupled to the first or second conductive layers of the storage capacitor and the stationary electrode of an IMOD display element. In some implementations, electrically coupling the drain of the at least one switch to the display element and the at least one layer of the optical mask structure can include forming a via between the display element and the storage capacitor. For example, a via similar to vias 160 discussed above can be utilized to electrically coupled the at least one switch to the display element and the at least one layer of the optical mask structure. Many additional steps may be employed before, in the middle of, or after the illustrated sequence, but such steps are omitted here for clarity of the description.

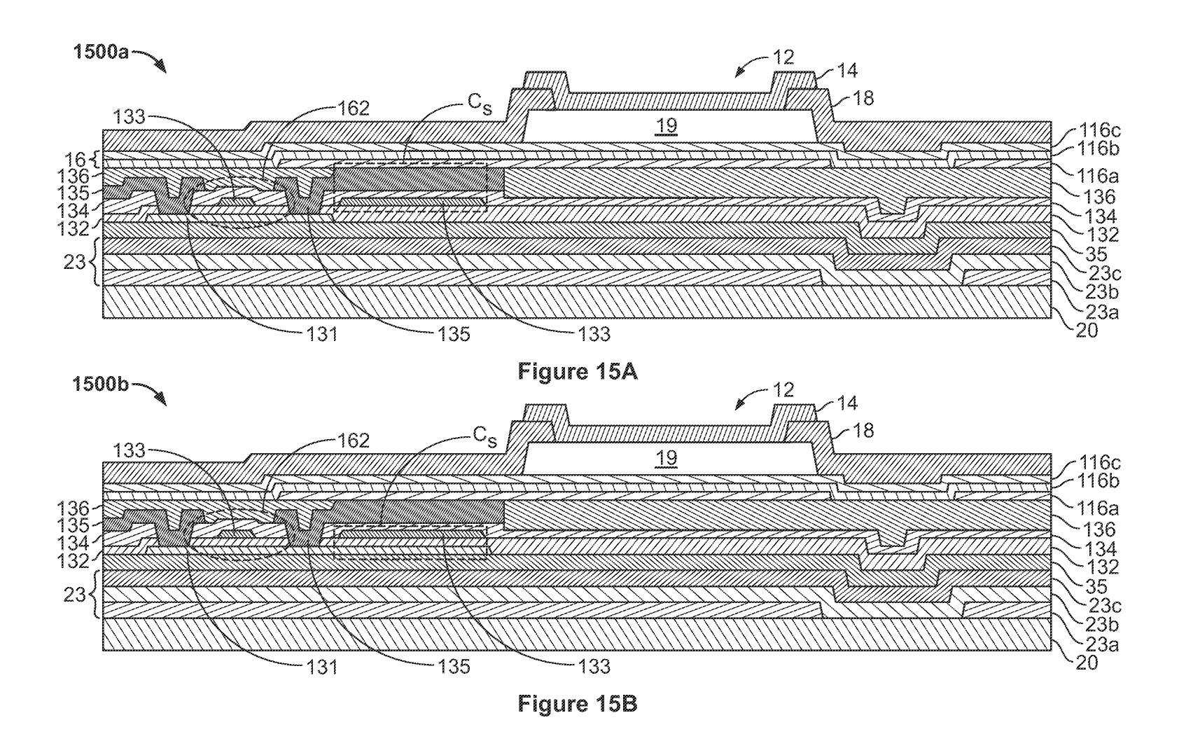

FIGS. 15A and 15B show cross-sectional views of examples of one display element 12 in an active-matrix array 1500 of display elements having an associated storage capacitor Cₛ integrated at least in part with a thin-film transistor 162. As with FIGS. 11L-11O, 12, and 13B, the display elements 12 illustrated in FIGS. 15A and 15B would not be visible in the illustrated cross-sectional view but is shown nonetheless to demonstrate the relationship between the storage capacitor Cₛ, the TFT 162, and the display element 12.

As with the active-matrix arrays described above, the arrays 1500 of FIGS. 15A and 15B can include a TFT 162 that is electrically coupled by a source/drain layer 135 to a stationary electrode 116a of an optical stack 16. The TFT 162 can also be electrically coupled to an associated storage capacitor Cₛ. In this way, the storage capacitor Cₛ can increase a capacitance associated with the display element 12, thereby reducing pixel leakage, reducing drive voltage and/or improving an image refresh of the array 1500. However, in contrast to the arrays described above with respect to FIGS. 11A-13B, the storage capacitors Cₛ can be formed at least in part by one or more layers of the TFT 162.

For example, as shown in FIG. 15A, in some implementations, one electrode of the storage capacitor Cₛ can be formed by the source/drain layer 135 and the other electrode of the storage capacitor Cₛ can be formed by the material used for the gate layer 133 of the TFT 162. In this way, the storage capacitor Cₛ can be formed using the same deposition steps described above used to form the TFT 162 and the storage capacitor Cₛ can be formed without requiring additional real estate or space within the array 1500a. In some implementations, the electrodes of the storage capacitor Cₛ can be isolated from one another by the spacer dielectric layer 134 that is deposited over the gate layer 133 (as described with reference to FIG. 11G).

Turning now to FIG. 15B, in some implementations, one electrode of the storage capacitor Cₛ can be formed by the active layer 131 of the TFT 162 and the other electrode of the storage capacitor Cₛ can be formed by the material used for the gate layer 133. For example, during the active layer 131 of the TFT 162 can be patterned to extend beyond the gate layer 133 (to the right of the gate layer 133 as shown in FIG. 15B) and this extension can form a conductive layer or electrode of the of the storage capacitor Cₛ. Further, the second electrode of the storage capacitor Cₛ can be formed during the same operation or block used to form the gate layer 133. In this way, the storage capacitor Cₛ can be formed using the same deposition steps described above used to form the TFT without requiring additional real estate or space within the array 1500b. As shown, the electrodes of the storage capacitor Cₛ can be isolated from one another by the spacer dielectric layer 134 that is deposited over the gate layer 133.

In each of the implementations shown in FIGS. 15A and 15B, the storage capacitor Cₛ can include one or more layers of the TFT 162 and can be formed in a plane between the plane of the display element 12 and the plane of the optical mask structure 23. In this way, the optical mask structure 23 may extend continuously over the storage capacitor Cₛ to reduce the reflectivity between display elements and improve the overall contrast of the arrays 1500.

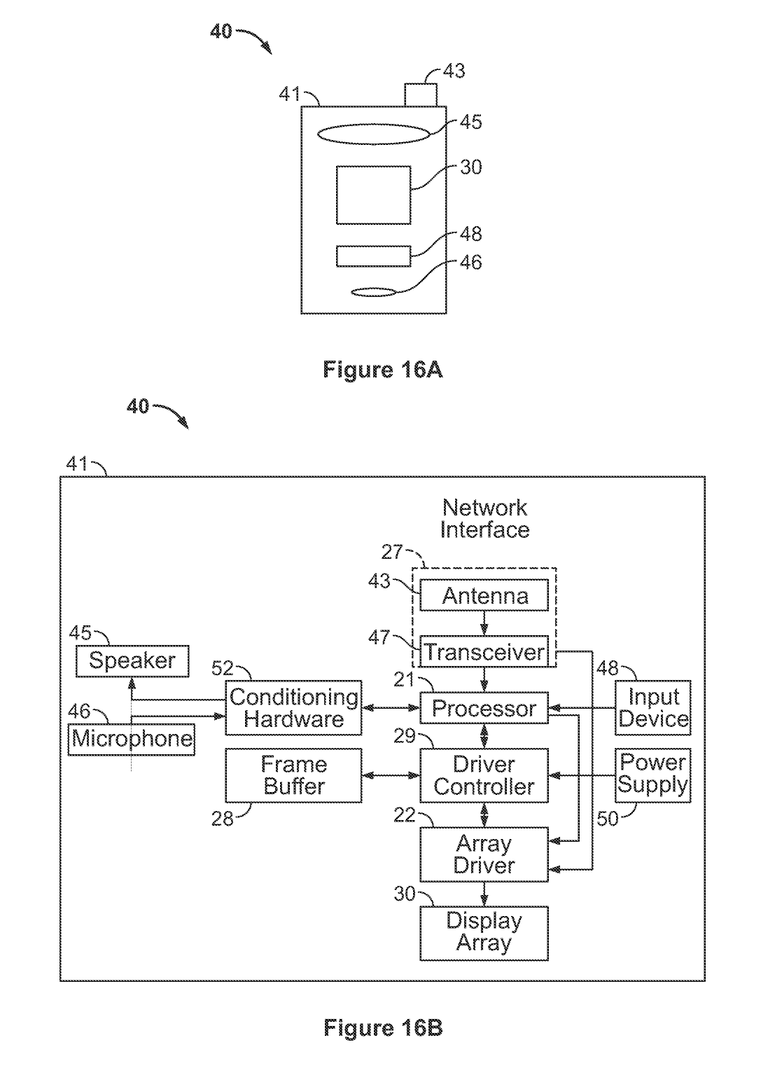

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
an array including at least a first display element and a second display element, each display element including a first electrode and a second electrode;
at least one switch configured to control a flow of charge between a source and the first display element;
a storage capacitor having a first capacitor electrode and a second capacitor electrode, the first capacitor electrode electrically connected to the first electrode of the first display element; and
at least one interferometric optical mask structure disposed in a non-active area of the array between the first display element and the second display element, the optical mask structure including
a partially reflective and partially transmissive and partially absorptive first conductive layer;
a reflective second conductive layer; and
a spacer layer disposed between the first conductive layer and the second conductive layer, wherein one of the first capacitor electrode and the second capacitor electrode includes one of the first conductive layer and the second conductive layer.

2. The device of claim 1, wherein the one of the first capacitor electrode and the second capacitor electrode includes the first conductive layer and wherein an other of the first capacitor electrode and the second capacitor electrode includes the second conductive layer.

3. The device of claim 1, further comprising:
a third conductive layer formed over the second conductive layer; and
a second spacer layer disposed between the third conductive layer and the second conductive layer, the third conductive layer and the second conductive layer forming the storage capacitor.

4. The device of claim 1, wherein the first conductive layer includes chromium.

5. The device of claim 4, wherein the second conductive layer includes aluminum or molybdenum.

6. The device of claim 5, wherein the spacer layer includes a transparent insulating material.

7. The device of claim 1, wherein the at least one switch includes a thin-film transistor.

8. The device of claim 7, wherein the thin-film transistor includes a drain that is electrically coupled to the second conductive layer and to the first electrode.

9. The device of claim 7, wherein the thin-film transistor includes a drain that is electrically coupled to the first conductive layer and to the first electrode.

10. The device of claim 9, further comprising a passivation layer disposed between at least a portion of the optical mask structure and the first display element.

11. The device of claim 9, further comprising a transistor contact layer electrically coupled to the drain of thin-film transistor and to the first electrode of the first display element.

12. The device of claim 11, wherein the second conductive layer of the optical mask structure is disposed over the first conductive layer of the optical mask structure, wherein a portion of the second conductive layer and the spacer layer is patterned to form an opening, and wherein a portion of the transistor contact layer contacts the first conductive layer in the opening.

13. The device of claim 1, wherein the first display element is an interferometric modulator (IMOD) display element.

14. The device of claim 13, wherein the first electrode is a stationary electrode and the second electrode is a movable electrode.

15. The device of claim 1, further comprising:
a display, wherein the display includes the first and second display elements;
a processor that is configured to communicate with the display, the processor being configured to process image data; and
a memory device that is configured to communicate with the processor.

16. The device of claim 15, further comprising a driver circuit configured to address at least the first display element by asserting a scan line to turn the at least one switch on and by charging at least the first display element and the storage capacitor via a data line.

17. The device of claim 16, further comprising a controller configured to send at least a portion of the image data to the driver circuit.

18. The device of claim 17, further comprising an image source module configured to send the image data to the processor.

19. The device of claim 15, further comprising an input device configured to receive input data and to communicate the input data to the processor.

20. A method of forming a device, the method comprising:
forming an optical mask structure for masking an optically non-active portion of the device, the optical mask structure including a partially reflective and partially transmissive and partially absorptive first conductive layer, a reflective second conductive layer, and a spacer layer disposed between the first and second conductive layers;
forming a storage capacitor having a first capacitor electrode and a second capacitor electrode, wherein one of the first capacitor electrode and the second capacitor electrode includes one of the first conductive layer and the second conductive layer;
forming at least one switch configured to control a flow of charge between a source and a drain;
forming a display element over the optical mask structure, the display element including a first electrode and a second electrode; and
electrically coupling the drain of the at least one switch to the display element and at least one layer of the optical mask structure.

21. The method of claim 20, wherein forming the at least one switch includes forming a thin-film transistor.

22. The method of claim 21, wherein electrically coupling the drain of the at least one switch to the display element and the storage capacitor includes electrically coupling the drain to the second conductive layer and the first electrode.

23. The method of claim 21, wherein electrically coupling the drain of the at least one switch to the display element and the storage capacitor includes electrically coupling the drain to the first conductive layer and the first electrode.

24. The method of claim 20, wherein forming the display element includes forming an interferometric modulator (IMOD).

25. A device, comprising:
means for controlling a flow of charge between a source and a drain;
means for displaying information, the displaying means being electrically coupled to the drain of the charge controlling means; and
means for interferometrically masking light in a non-active area of the displaying means, the masking means forming at least part of a storage capacitor that is electrically coupled to the drain of the charge controlling means.

26. The device of claim 25, wherein the displaying means includes an interferometric modulator (IMOD).

27. The device of claim 25, wherein the charge controlling means includes at least one switch.

28. The device of claim 23, wherein the masking means includes a partially reflective and partially transmissive and partially absorptive first conductive layer, a reflective second conductive layer, and a spacer layer disposed between the first conductive layer and the second conductive layer, wherein one of the first conductive layer and the second conductive layer includes a capacitor electrode of the storage capacitor.

29. A device comprising:
a first display element having a first electrode and a second electrode, the second electrode being movable relative to the first electrode;
at least one switch configured to control a flow of charge between a source and the first display element, the at least one switch including a first conductive layer, a second conductive layer, and a source/drain layer electrically connected to the first electrode of the first display element; and
a storage capacitor having a first capacitor electrode and a second capacitor electrode, the first capacitor electrode electrically connected to the first electrode of the display element, wherein one of the first capacitor electrode and the second capacitor electrode includes one of the first conductive layer, the second conductive layer, and the source/drain of the at least one switch.

30. The device of claim 29, wherein the at least one switch includes a thin-film transistor having an active layer and a gate layer, wherein the first conductive layer includes the active layer, and wherein the second conductive layer includes the gate layer.

31. The device of claim 30, wherein the first capacitor electrode includes the source/drain layer and wherein the second capacitor electrode includes a conductive material that includes the same material as the gate layer.

32. The device of claim 30, wherein the first capacitor electrode includes the active layer and wherein the second capacitor electrode includes a conductive material that includes the same material as the gate layer.

33. The device of claim 29, further comprising:
a second display element; and
at least one interferometric optical mask structure disposed between the first display element and the second display element.

34. The device of claim 33, wherein the at least one switch is disposed at least partially between the optical mask structure and the first display element.

35. A method of forming a device, the method comprising:
forming a display element having a first electrode and a second electrode, the second electrode being movable relative to the first electrode;
forming at least one switch configured to control a flow of charge between a source and the first display element, the at least one switch including a first conductive layer, a second conductive layer, and a source/drain layer electrically connected to the first electrode of the first display element;
forming a storage capacitor having a first capacitor electrode and a second capacitor electrode, wherein one of the first capacitor electrode and the second capacitor electrode includes one of the first conductive layer, the second conductive layer, and the source/drain of the at least one switch; and
electrically connecting the first capacitor electrode to the first electrode of the display element.

36. The method of claim 35, wherein forming the at least one switch includes forming a thin-film transistor having an active layer and a gate layer, wherein the first conductive layer includes the active layer, and wherein the second conductive layer includes the gate layer.

37. The method of claim 36, wherein the first capacitor electrode includes the source/drain layer and wherein the second capacitor electrode includes a conductive material that includes the same material as the gate layer.

38. The method of claim 36, wherein the first capacitor electrode includes the active layer and wherein the second capacitor electrode includes a conductive material that includes the same material as the gate layer.

39. The method of claim 35, further comprising:
providing a second display element; and
providing at least one interferometic optical mask structure between the first display element and the second display element.

40. The method of claim 39, wherein the at least one switch is disposed at least partially between the optical mask structure and the first display element.
